(19) United States
(12) Patent Application Publication
(10) Pub. No.: US 2019/0103838 A1
(43) Pub. Date: Apr. 4, 2019

(54) MODULATOR AND MODULATION METHOD

(71) Applicant: SONY CORPORATION, TOKYO (JP)

(72) Inventors: YOSHINOBU KAWASAKI, KANAGAWA (JP); YUJI KIYOTA, KANAGAWA (JP)

(21) Appl. No.: 16/085,881

(22) PCT Filed: Mar. 13, 2017
(86) PCT No.: PCT/JP2017/009873

§ 371 Date: Sep. 17, 2018

(30) Foreign Application Priority Data
Mar. 25, 2016 (JP) 2016-061633

(51) Int. Cl. H03C 1/62; H03C 1/54; H04L 27/04; H04L 27/06

(52) U.S. Cl. CPC H03C 1/62; H04L 27/06; H04L 27/04; H03C 1/54

(57) ABSTRACT

The present technology relates to a modulator and a modulation method for enabling provision of a highly convenient modulator. The modulator is configured to be input a first signal corresponding to one of a positive signal and a negative signal constituting a baseband signal of a differential signal, and a second signal having the same level as the first signal in one of an H level section in which the one signal is at an H level and an L level section in which the one signal is at an L level, and configured to generate a modulation signal obtained by modulating a carrier with the first and second signals to generate a modulation signal that is the amplitude shift keying (ASK)-modulated carrier with the baseband signal. The present technology can be applied to a case of modulating a carrier according to a baseband signal, for example.

### TECHNICAL FIELD

The present technology relates to a modulator and a modulation method, and in particular to a modulator and a modulation method for enabling provision of a highly convenient modulator, for example.

### BACKGROUND ART

As a modulator used in a communication system, a modulator configured by, for example, a plurality of double balanced mixers (DBMs) and performing quadrature phase shift keying (QPSK) modulation has been proposed (for example, see Patent Document 1).

### CITATION LIST

### Patent Document

Patent Document 1: International Publication No. 2002/030406

### SUMMARY OF THE INVENTION

### Problems to be Solved by the Invention

In the modulator described in Patent Document 1, the DBM is configured by a cascode circuit having a cascode stage and a gain stage. An oscillator that outputs a carrier (carrier wave) is connected to the cascode stage, and the carrier output by the oscillator is input to the cascode stage. Meanwhile, a baseband (BB) signal as data to be transmitted is input to the gain stage.

In the cascode circuit, the influence of the cascode stage and the gain stage on respective nodes with respect to temporal change of output is smaller on the node connected to the gain stage. In other words, the input impedance of the cascode stage is easily changed due to the influence of the temporal change of the output of the cascode circuit and the temporal change of the input impedance of a circuit connected to the output of the cascode circuit.

Furthermore, in the case where the oscillator is configured without a phase lock loop (PLL), the oscillation frequency of the oscillator, in other words, the frequency of the carrier is easily changed due to the influence of noise and the temporal change of a load connected to the oscillator.

As a method of suppressing the change of the oscillation frequency of the oscillator as described above, there is a method of providing a buffer circuit at the output of the oscillator. However, providing the buffer circuit results in an increase in power consumption, an increase in a circuit scale, and the like, and impairs the convenience of the modulator.

Meanwhile, in the case where the carrier and the BB signal itself are input to the modulator configured by the DBM, as described in Patent Document 1, modulation of the carrier performed by the modulator is phase modulation such as binary phase shift keying (BPSK), and it is difficult to perform amplitude shift keying (ASK) modulation.

The present technology has been made in view of the foregoing, and enables provision of a modulator capable of suppressing change of an oscillation frequency of an oscillator, and a highly convenience modulator such as a modulator capable of performing ASK modulation, for example.

### Solutions to Problems

A first modulator of the present technology is a modulator configured to be input a first signal corresponding to one of a positive signal and a negative signal constituting a baseband signal of a differential signal, and a second signal at the same level as the first signal in one of an H level section in which the one of the positive signal and the negative signal is at an H level and an L level section in which the one of the positive signal and the negative signal is at an L level, and configured to modulate a carrier with the first and second signals to generate a modulation signal that is the amplitude shift keying (ASK)-modulated carrier with the baseband signal.

A first modulation method of the present technology is a modulation method including modulating a carrier with a first signal corresponding to one of a positive signal and a negative signal constituting a baseband signal of a differential signal, and a second signal at the same level as the first signal in one of an H level section in which the one of the positive signal and the negative signal is at an H level and an L level section in which the one of the positive signal and the negative signal is at an L level, to generate a modulation signal that is the amplitude shift keying (ASK)-modulated carrier with the baseband signal.

In the first modulator and the first modulation method of the present technology, the carrier is modulated with the first signal corresponding to one of a positive signal and a negative signal constituting a baseband signal of a differential signal, and the second signal at the same level as the first signal in one of an H level section in which the one of the positive signal and the negative signal is at an H level and an L level section in which the one of the positive signal and the negative signal is at an L level, and the modulation signal that is the amplitude shift keying (ASK)-modulated carrier with the baseband signal is generated.

A second modulator of the present technology is a modulator configured by a cascode circuit including a gain stage to which a carrier of a differential signal is input, and a cascode stage to which a baseband signal is input, and configured to modulate the carrier with the baseband signal.

A second modulation method of the present technology is a modulation method including inputting a differential signal of a carrier to a gain stage of a cascode circuit including the gain stage and a cascode stage, and inputting a baseband signal to the cascode stage, and modulating the carrier with the baseband signal.

In the second modulator and the second modulation method of the present technology, the differential signal of a carrier is input to the gain stage of the cascode circuit including the gain stage and the cascode stage and the baseband signal is input to the cascode stage, and the carrier is modulated with the baseband signal.

Note that the modulator may be an independent device or an internal block constituting one device.

### Effects of the Invention

According to the present technology, a highly convenient modulator can be provided.

Note that the effects described herein are not necessarily limited and may be any of the effects described in the present disclosure.

### BRIEF DESCRIPTION OF DRAWINGS

FIG. 1 is a diagram illustrating a configuration example of a modulation system using a single mixer as a modulator.

FIG. 2 is a diagram illustrating a configuration example of a modulation system using a single balanced mixer as a modulator.

FIG. 3 is a diagram illustrating a configuration example of a modulation system using a DBM as a modulator.

FIG. 4 is a diagram illustrating a configuration example of an embodiment of a modulation system to which the present technology is applied.

FIG. 5 is a diagram illustrating a first configuration example of a cascode stage 102.

FIG. 6 is a diagram illustrating a simulation result of simulation of measuring an oscillation frequency error.

FIG. 7 is a diagram for describing an operation of a modulator 100.

FIG. 8 is a diagram illustrating a first configuration example of a conversion unit 90.

FIG. 9 is a diagram illustrating a second configuration example of the conversion unit 90.

FIG. 10 is a diagram illustrating a second configuration example of the cascode stage 102.

FIG. 11 is a diagram illustrating a third configuration example of the cascode stage 102.

### MODE FOR CARRYING OUT THE INVENTION

<Configuration Example of Modulation System Using Single Mixer as Modulator>

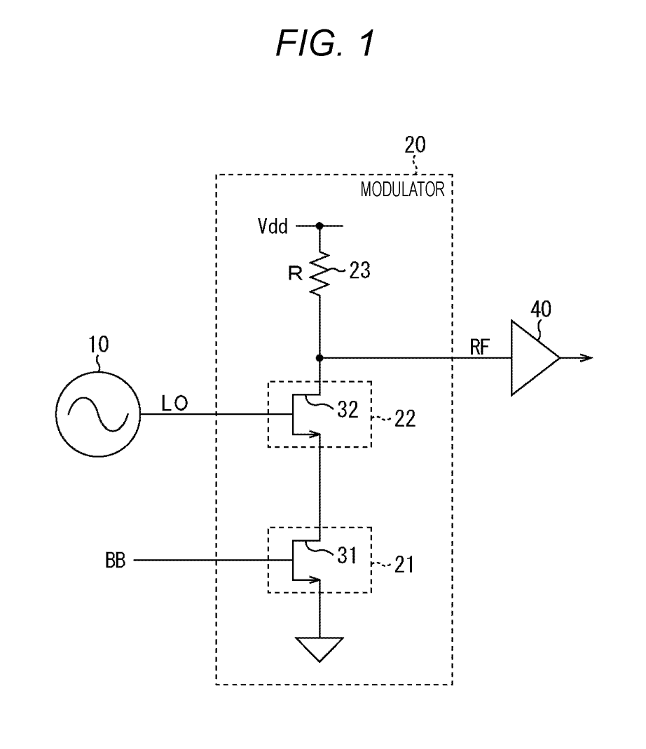

FIG. 1 is a diagram illustrating a configuration example of a modulation system using a single mixer as a modulator.

In FIG. 1, the modulation system includes an oscillator 10, a modulator 20, and an amplifier 40.

The oscillator 10 generates and outputs a carrier having a predetermined oscillation frequency by oscillation.

The modulator 20 is a single mixer and is a cascode circuit having a gain stage 21, a cascode stage 22, and a resistor 23.

The gain stage 21 is configured by an FET 31 that is a negative (N) channel metal oxide semiconductor field effect transistor (MOSFET).

The cascode stage 22 is configured by an FET 32 that is an N channel MOSFET.

A source of the FET 31 is grounded, and a BB signal is input to a gate of the FET 31. A drain of the FET 31 is connected to a source of the FET 32.

The oscillator 10 is connected to a gate of the FET 32, and a carrier LO output by the oscillator 10 is input to the gate.

A drain of the FET 32 is connected to one end of the resistor 23, and the other end of the resistor 23 is connected to a power supply Vdd.

An input terminal of the amplifier 40 is connected to a connection point between (the FET 32 of) the cascode stage 22 and the resistor 23. The amplifier 40 amplifies and outputs a signal at the connection point between the cascode stage 22 and the resistor 23.

In the modulation system configured as described above, ASK modulation in which the amplitude of the carrier output by the oscillator 10 is changed is performed according to (a level of) the BB signal.

In other words, in the modulator 20, the amplitude of a current flowing in the FET 32 according to the carrier LO input to the gate of the FET 32 is changed according to the BB signal input to the gate of the FET 31, whereby the ASK Modulation of the carrier is performed.

A modulation signal generated by the ASK modulation in the modulator 20 appears at the connection point between the cascode stage 22 and the resistor 23 and is output through the amplifier 40.

<Configuration Example of Modulation System Using Single Balanced Mixer as Modulator>

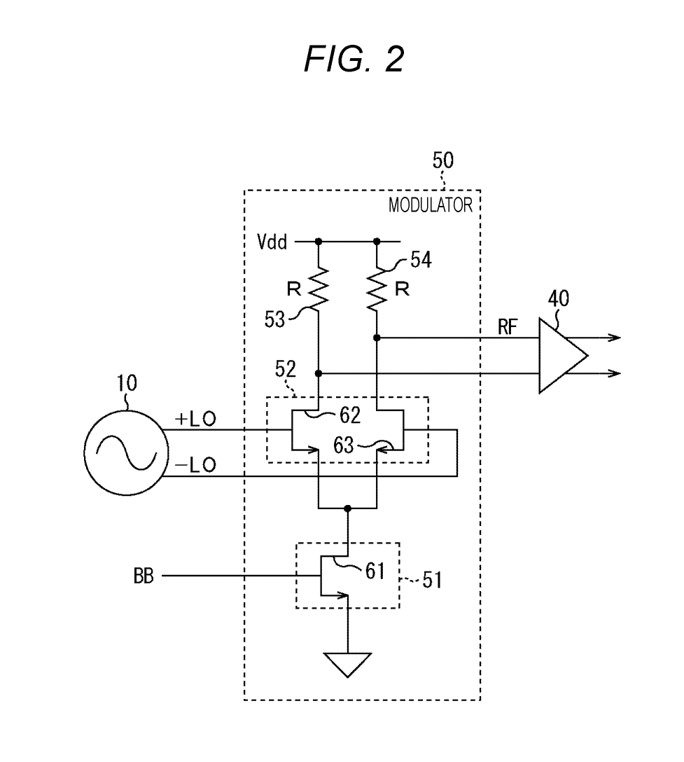

FIG. 2 is a diagram illustrating a configuration example of a modulation system using a single balanced mixer as a modulator.

Note that, in the drawing, a portion corresponding to the case of FIG. 1 is denoted by the same reference numeral, and description of the portion is herein appropriately omitted.

In FIG. 2, the modulation system includes an oscillator 10, an amplifier 40, and a modulator 50.

Accordingly, the modulation system in FIG. 2 is common to the case in FIG. 1 in including the oscillator 10 and the amplifier 40, and is different from the case in FIG. 1 in including the modulator 50 in place of the modulator 20.

Furthermore, in FIG. 2, the oscillator 10 outputs a carrier of a differential signal, which is different from the case in FIG. 1.

Here, the oscillator 10 can output the carrier of a differential signal. The differential signal as a carrier is configured by so-called positive signal and negative signal. One of the positive signal and the negative signal is a signal obtained by inverting the other signal with respect to a level (common potential) (for example, GND) common to the positive signal and the negative signal.

Note that in FIG. 1, the oscillator 10 outputs a carrier of a single-ended signal corresponding to, for example, the positive signal, which is one of the positive signal and the negative signal.

The modulator 50 is a single balanced mixer and is a cascode circuit having a gain stage 51, a cascode stage 52, and resistors 53 and 54.

The gain stage 51 is configured by an FET 61 that is an N channel MOSFET.

The cascode stage 52 is configured by a differential pair configured by FETs 62 and 63 that are N channel MOSFETs.

A source of the FET 61 is grounded, and a BB signal is input to a gate of the FET 61. A drain of the FET 61 is connected to sources of the FETs 62 and 63. Therefore, the sources of the FETs 62 and 63 are connected to each other.

The oscillator 10 is connected to gates of the FETs 62 and 63. A positive signal +LO and a negative signal −LO constituting the carrier of the differential signal output by the oscillator 10 are supplied to the gates of the FETs 62 and 63, respectively.

A drain of the FET 62 is connected to one end of the resistor 53, and the other end of the resistor 53 is connected to a power supply Vdd.

A drain of the FET 63 is connected to one end of the resistor 54, and the other end of the resistor 54 is connected to the power supply Vdd.

Note that, in FIG. 2, a connection point between (the FET 62 of) the cascode stage 52 and the resistor 53 and a connection point between (the FET 62 of) the cascode stage 52 and the resistor 53 are connected to two input terminals (a non-inverting input terminal and an inverting input terminal) of the amplifier 40, respectively.

In the modulation system configured as described above, ASK modulation in which the amplitude of the carrier output by the oscillator 10 is changed is performed according to the BB signal.

In other words, in the modulator 50, the amplitude of currents flowing in the FETs 62 and 63 according to the positive signal +LO and the negative signal −LO of the carrier input to the gates of the FETs 62 and 63 is changed according to the BB signal input to the gate of the FET 31, whereby the ASK Modulation of the carrier is performed.

A modulation signal generated by the ASK modulation in the modulator 50 appears at the connection points between the cascode stage 52 and the respective resistors 53 and 54. This modulation signal is a differential signal and is output via the amplifier 40.

<Configuration Example of Modulation System Using DBM as Modulator>

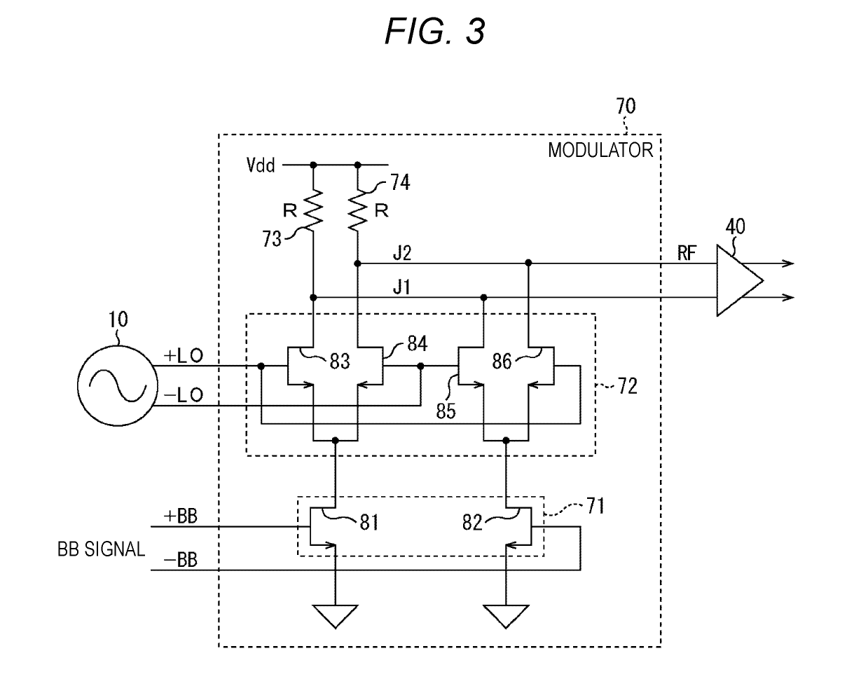

FIG. 3 is a diagram illustrating a configuration example of a modulation system using a DBM as a modulator.

Note that, in the drawing, a portion corresponding to the case of FIG. 1 is denoted by the same reference numeral, and description of the portion is herein appropriately omitted.

In FIG. 3, the modulation system includes an oscillator 10, an amplifier 40, and a modulator 70.

Accordingly, the modulation system in FIG. 3 is common to the case in FIG. 1 in including the oscillator 10 and the amplifier 40, and is different from the case in FIG. 1 in including the modulator 70 in place of the modulator 20.

Note that, in FIG. 3, the oscillator 10 outputs a carrier of a differential signal, similarly to FIG. 2.

Moreover, in FIG. 3, a differential signal configured by a positive signal +BB and a negative signal −BB is input to the modulator 70, as the BB signal.

The modulator 70 is a DBM and is a cascode circuit having a gain stage 71, a cascode stage 72, and resistors 73 and 74.

The gain stage 71 is configured by FETs 81 and 82 that are N channel MOSFETs.

The cascode stage 72 is configured by a differential pair configured by FETs 83 and 84 that are N channel MOSFET, and a differential pair configured by FETs 85 and 86 that are N channel MOSFETs.

A source of the FET 81 is grounded, and the positive signal +BB of a BB signal is input to a gate of the FET 81. A drain of the FET 81 is connected to sources of the FETs 83 and 84. Therefore, the sources of the FETs 83 and 84 are connected to each other.

A source of the FET 82 is grounded, and the negative signal −BB of the BB signal is input to a gate of the FET 82. A drain of the FET 82 is connected to sources of the FETs 85 and 86. Therefore, the sources of the FETs 85 and 86 are connected to each other.

The oscillator 10 is connected to gates of the FETs 83 and 84. A positive signal +LO and a negative signal −LO constituting the carrier of the differential signal output by the oscillator 10 are supplied to the gates of the FETs 83 and 84, respectively.

A drain of the FET 83 is connected to one end of the resistor 73, and the other end of the resistor 73 is connected to a power supply Vdd.

A drain of the FET 84 is connected to one end of the resistor 74, and the other end of the resistor 74 is connected to the power supply Vdd.

The oscillator 10 is connected to gates of the FETs 85 and 86. The positive signal +LO and the negative signal −LO constituting the carrier of the differential signal output by the oscillator 10 are supplied to the gates of the FETs 85 and 86, respectively.

A drain of the FET 85 is connected to the one end of the resistor 73, and a drain of the FET 86 is connected to the one end of the resistor 74.

From the above, the drains of the FETs 83 and 85 and the resistor 73 are connected, the drains of the FETs 84 and 86 and the resistor 74 are also connected. The connection point between the drains of the FETs 83 and 85 and the resistor 73 is referred to as a connection point J1 and the connection point between the drains of the FETs 84 and 86 and the resistor 74 is described as a connection point J2.

In FIG. 3, the connection points J1 and J2 are respectively connected to two input terminals (a non-inverting input terminal and an inverting input terminal) of the amplifier 40.

In the modulation system configured as described above, BPSK modulation in which the phase of the carrier output by the oscillator 10 is changed is performed according to the BB signal.

In other words, in the modulator 70, roughly speaking, in the case where the FET 81 to which the positive signal +BB is input (to the gate) is ON and the FET 82 to which the negative signal −BB is input is OFF, a signal corresponding to a current corresponding to the positive signal +LO of the carrier, the current flowing in the FET 83, appears at the connection point J1, for example. Furthermore, in the case where the FET 81 is OFF and the FET 82 is ON, a signal corresponding to a current corresponding to the negative signal −LO of the carrier, the current flowing in the FET 85, appears at the connection point J1.

Accordingly, a signal obtained by BPSK-modulating the carrier appears at the connection point J1 according to the BB signal.

Furthermore, a signal obtained by inverting the signal appearing at the connection point J1 appears at the connection point J2.

Accordingly, a modulation signal that is a BPSK-modulated carrier and is a differential signal appears at the connection points J1 and J2 according to the BB signal.

The modulation signal of the differential signal appearing at the connection points J1 and J2 is output via the amplifier 40.

The above-described modulation systems in FIGS. 1 to 3 can be applied to modulation of carriers having various frequencies.

By the way, in modulation of a so-called millimeter wave carrier having a frequency of about 30 to 300 GHz, that is, a wavelength of about 1 to 10 mm, a carrier of a differential signal is often used where the oscillator 10 is caused to have a differential configuration.

As described above, in the case of using the carrier of a differential signal, the oscillator 10 is connected to the cascode stage 52 or 72 that is configured by a differential pair capable of receiving the differential signal. Then, the carrier of the differential signal output by the oscillator 10 is input to ((the FETs 62 and 63, FETs 83 and 84, or FETs 85 and 86) of the differential pair constituting) the cascode stage 52 or 72.

Here, to simplify the description, attention is paid to, for example, the modulator 70, from among the modulator 20 in FIG. 1, the modulator 50 in FIG. 2, and the modulator 70 in FIG. 3 that are cascode circuits.

The modulator 70, which is a cascode circuit, includes the gain stage 71 and the cascode stage 72, and the influence of the connection points J1 and J2 as the output terminals of the modulator 70 on the gain stage 71 and the cascode stage 72 with respect to the temporal change is smaller on the gain stage 71 than on the cascode stage 72.

In other words, the input impedance of the cascode stage 72 is easily changed due to the influence of the circuit connected to the connection points J1 and J2 as the output terminals of the modulator 70 that is a cascode circuit, in other words, the input impedance of the amplifier 40. Moreover, the input impedance of the cascode stage 72 is easily changed due to the influence of the BB signal input to the gain stage 71 on a preceding stage of the cascode stage 72.

In the case where the input impedance of the cascode stage 72 is changed, the frequency of the carrier, which is an oscillation frequency of the oscillator 10 connected to the cascode stage 72, is changed due to the change of the input impedance of the cascode stage 72.

As a method of suppressing the change of the oscillation frequency of the oscillator 10 like above, there are, for example, a method of configuring the oscillator 10 using a PLL, a method of providing a buffer circuit at the output of the oscillator 10 and not transmitting the change of the input impedance of the cascode stage 72 to the oscillator 10, and the like.

However, configuring the oscillator 10 using a PLL results in, for example, an increase in the cost and size of the oscillator 10, an increase in the power consumption, and impairs the convenience of the modulator 70.

In the case where the oscillator 10 is configured without (fixation of the frequency by) a PLL, change of the oscillation frequency of the oscillator 10 due to the influence of the change of the input impedance of the cascode stage 72 can be suppressed by providing the buffer circuit to the output of the oscillator 10.

However, providing the buffer circuit results in an increase in the power consumption, an increase in the circuit scale, and the like, and still impairs the convenience of the modulator 70.

The above point is similar in the modulators 20 and 50 in addition to the modulator 70.

Furthermore, as described above, the modulator 20 that is a single mixer and the modulator 50 that is a single balanced mixer perform the ASK modulation, but the modulator 70 as a DBM performs the BPSK modulation that is phase modulation.

However, it is convenient if the ASK modulation can be performed in the DBM modulator.

Therefore, hereinafter, a highly convenience modulator capable of suppressing change of the oscillation frequency of the oscillator 10 and capable of performing the ASK modulation using the mixer of the DBM or the like in which the phase modulation is performed, even if the oscillator 10 configured without a PLL is used without providing a buffer circuit will be described.

<Embodiment of Modulation System to Which Present Technology is Applied>

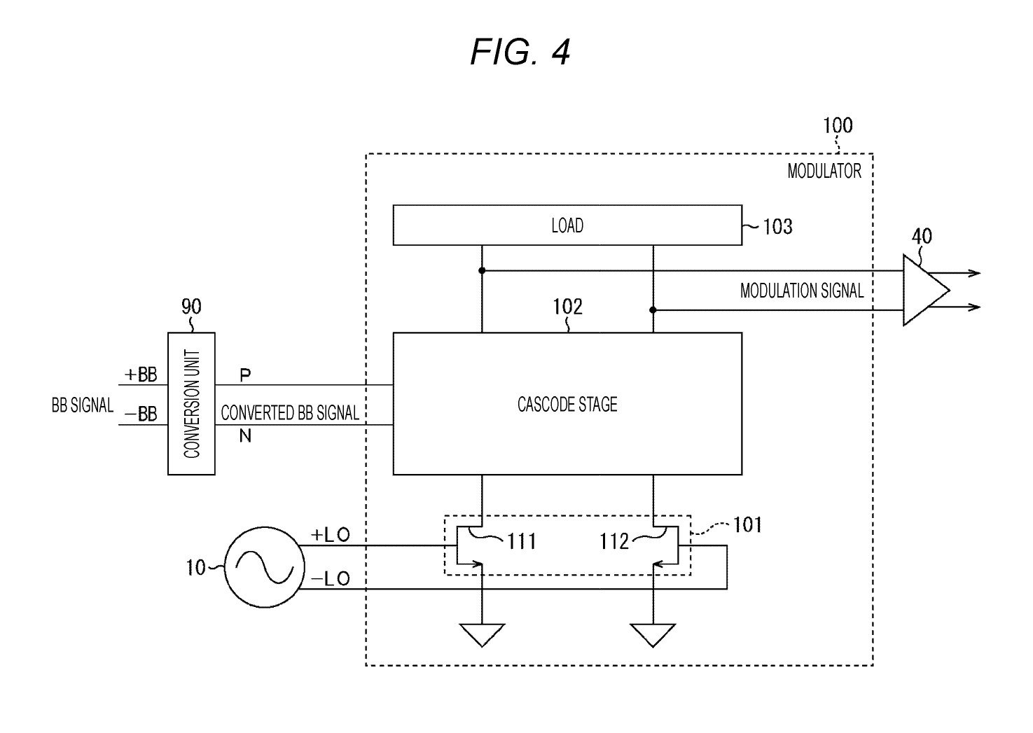

FIG. 4 is a diagram illustrating a configuration example of an embodiment of a modulation system to which the present technology is applied.

Note that, in the drawing, a portion corresponding to the cases of FIGS. 1 to 3 is denoted by the same reference numeral, and description of the portion is herein appropriately omitted.

In FIG. 4, the modulation system includes an oscillator 10, an amplifier 40, a conversion unit 90, and a modulator 100.

Accordingly, the modulation system in FIG. 4 is common to the cases in FIGS. 1 to 3 in including the oscillator 10 and the amplifier 40.

However, the modulation system in FIG. 4 is different from the cases in FIGS. 1 to 3 in including the modulator 100 in place of the modulator 20, 50, or 70 and in newly providing the conversion unit 90.

Note that, in FIG. 4, the oscillator 10 outputs a carrier of a differential signal configured by a positive signal +LO and a negative signal −LO, similarly to FIGS. 2 and 3. Moreover, in FIG. 4, a BB signal is a differential signal configured by a positive signal +BB and a negative signal −BB, similarly to FIG. 3.

The BB signal of a differential signal is supplied to the conversion unit 90. The conversion unit 90 converts the BB signal of the differential signal and outputs a converted BB signal that is the BB signal after conversion.

The converted BB signal is configured by a first signal P and a second signal N.

The first signal P is a signal corresponding to one of the positive signal +BB and the negative signal −BB of the BB signal.

The “signal corresponding to one of the positive signal +BB and the negative signal −BB of the BB signal” includes a signal having information equivalent to the one signal (for example, a signal obtained by offsetting the one signal or amplifying the one signal), in addition to the one signal itself that is the positive signal +BB or the negative signal −BB).

The second signal N is a signal at the same level as the first signal P in one of an H level section in which one of the positive signal +BB and the negative signal −BB is at an H level and an L level section in which the one signal is at an L level.

Accordingly, as the second signal N, a fixed-level signal fixed to the level of the first signal P in one of the H level section and the L level section can be adopted, for example.

Furthermore, for example, as the first signal P and the second signal N, signals obtained by offsetting one and the other of the positive signal +BB and the negative signal −BB in one of the H level section and the L level section such that the levels coincide with each other can be respectively adopted.

Note that the conversion unit 90 can output the BB signal of the differential signal as it is without conversion, in other words, can output the positive signal +BB and the negative signal −BB themselves of the BB signal as the first signal P and the second signal N.

Furthermore, the modulation system can be configured without providing the conversion unit 90. However, in the case of performing the ASK modulation, in other words, in the case of generating a modulation signal that is an ASK-modulated carrier according to the BB signal, in the modulation system, the BB signal needs to be converted into the first signal P corresponding to one of the positive signal +BB and the negative signal −BB of the BB signal and into the second signal N at the same level as the first signal P in one of the H level section and the L level section in the conversion unit 90.

The above point is similar in the modulation system described below.

The modulator 100 is a cascode circuit having a gain stage 101, a cascode stage 102, and a load 103.

The gain stage 101 is configured by two FETs 111 and 112 that are N channel MOSFETs.

The cascode stage 102 can have an arbitrary configuration as long as the modulator 100 serves as a cascode circuit.

The cascode stage 102 may be configured by two differential pairs or the like, for example, like the cascode stage 72 in FIG. 3. Note that the cascode stage 102 may be connected to a power supply (not illustrated) depending on the configuration of the cascode stage 102.

As the load 103, an arbitrary load can be adopted as long as the modulator 100 can be operated.

The load 103 is connected to the cascode stage 102 and is connected to a power supply (not illustrated). As the load 103, an inductance or the like can be adopted besides a resistor like the resistor 73 or 74, which is a load in the modulator 70 in FIG. 3, for example.

In the modulator 100 in FIG. 4, the oscillator 10 is connected to the gain stage 101, and the carrier output by the oscillator 10 is input to the gain stage 101 and the BB signal is input to the cascode stage 102.

In other words, in FIGS. 1 to 3, the oscillator 10 is connected to the cascode stage 22, 52, or 72, and the carrier output by the oscillator 10 is input to the cascode stage 22, 52, or 72 and the BB signal is input to the gain stage 21, 51, or 71, whereas in FIG. 4, the oscillator 10 is connected to a gain stage 101, and the carrier output by the oscillator 10 is input to the gain stage 101 and the BB signal is input to the cascode stage 102 via the conversion unit 90.

In the gain stage 101, a source of the FET 111 is grounded, and the positive signal +LO of the carrier is input to a gate of the FET 111. Therefore, a current according to the positive signal +LO of the carrier flows in the FET 111. A drain of the FET 111 is connected to the cascode stage 102.

Moreover, in the gain stage 101, a source of the FET 112 is grounded, and a negative signal −LO of the carrier is input to a gate of the FET 112. Therefore, a current according to the negative signal −LO of the carrier flows in the FET 112. A drain of the FET 112 is connected to the cascode stage 102.

In the cascode stage 102, the current flowing in the FETs 111 and 112, in other words, a current corresponding to the carrier flows according to the converted BB signal from the conversion unit 90, whereby a modulation signal that is a modulated carrier is generated (output) according to the BB signal, and flows between the cascode stage 102 and the load 103.

The modulation signal generated by the cascode stage 102 is a differential signal, for example, and is output via the amplifier 40 connected between the cascode stage 102 and the load 103. Here, as the amplifier 40, one differential amplifier capable of inputting both the positive signal and the negative signal of the modulation signal that is a differential signal can be adopted. Furthermore, as the amplifier 40, a total of two single-ended amplifiers: a single-ended amplifier to which one of the positive signal and the negative signal of the modulation signal that is a differential signal is input; and the other single-ended amplifier to which the other of the positive signal and the negative signal is input can be adopted.

As described above, in the modulator 100 in FIG. 4, the carrier output by the oscillator 10 is input to the gain stage 101 and the BB signal is input to the cascode stage 102.

In the modulator 100, the influence of the input impedance of the amplifier 40 connected to the output of the modulator 100 and the influence of the BB signal on the input impedance of the gain stage 101 are reduced by the influence of the cascode stage 102 existing between the oscillator 10, and the BB signal and the amplifier 40.

As described above, since the influence of the input impedance of the amplifier 40 and the influence of the BB signal on the input impedance of the gain stage 101 are reduced, change of the oscillation frequency of the oscillator 10 connected to the gain stage 101 due to the influence of the input impedance of the amplifier 40 and the influence of the BB signal can be suppressed.

Accordingly, even in the case where the oscillator 10 is configured without a PLL and a buffer circuit is not provided to the output of the oscillator 10, change of the oscillation frequency of the oscillator 10 is suppressed. As a result, an increase in the cost, the power consumption, and the circuit scale can be provided, and the highly convenient modulator 100 can be provided.

Note that, in FIG. 4, the modulator 100 is configured to input the carrier to the gain stage 101 and input the converted BB signal to the cascode stage 102. However, the modulator 100 can be configured to input the converted BB signal to the gain stage 101 and input the carrier to the cascode stage 102.

In the case where the first signal P corresponding to one of the positive signal +BB and the negative signal −BB of the BB signal and the second signal N at the same level as the first signal P in one of the H level section and the L level section are input to the modulator 100 as the converted BB signals, the ASK modulation can be performed even when each of the carrier and the converted BB signal is input to either the gain stage 101 or the cascode stage 102.

However, in the case where the converted BB signal is input to the gain stage 101 and the carrier is input to the cascode stage 102, the oscillation frequency of the oscillator 10 connected to the cascode stage 102 is easily change due to the influence of the input impedance of the amplifier 40 and the influence of the BB signal, similarly to the cases in FIGS. 1 to 3.

The above point is similar in the modulation system described below.

<First Configuration Example of Cascode Stage 102>

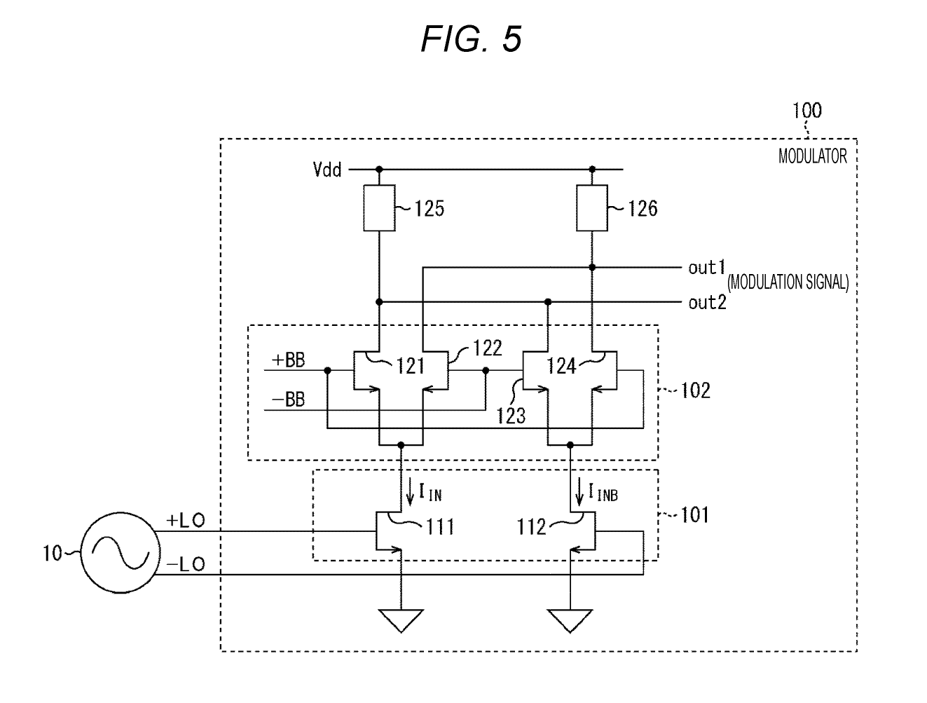

FIG. 5 is a diagram illustrating a first configuration example of the cascode stage 102 in FIG. 4.

Note that, in FIG. 5, loads 125 126 having predetermined impedance are provided as the load 103 in FIG. 4.

In FIG. 5, the cascode stage 102 is configured by two differential pairs: a differential pair configured by FETs 121 and 122 that are N channel MOSFETs; and a differential pair configured by FETs 123 and 124 that are N channel MOSFETs, and the BB signal itself is input to the cascode stage 102.

The positive signal +BB of the BB signal is supplied to gates of the FETs 121 and 124 as the first signal P of the converted BB signal.

The negative signal −BB of the BB signal is supplied to gates of the FETs 122 and 123 as the second signal N of the converted BB signal.

Drains of the FETs 121 and 123 are connected to one end of the load 125, and the other end of the load 125 is connected to a power supply Vdd.

Drains of the FETs 122 and 124 are connected to one end of the load 126, and the other end of the load 126 is connected to a power supply Vdd.

Sources of the FETs 121 and 122 are connected to each other, and a connection point between the sources is connected to the drain of the FET 111 of the gain stage 101.

Sources of the FETs 123 and 124 are connected to each other, and a connection point between the sources is connected to the drain of the FET 112 of the gain stage 101.

In FIG. 5, a signal appearing at an output terminal out1 connected to the connection point between the FETs 122 and 124, and the load 126 (hereinafter also referred to as a signal out1), and a signal appearing at an output terminal out2 connected to the connection point between the FETs 121 and 123, and the load 125 (hereinafter the signal is also referred to as a signal out2) are output as the modulation signals obtained by BPSK-modulating the carrier with the BB signal. The modulation signal is a differential signal, and the signals out1 and out2 are a positive signal and a negative signal constituting the modulation signal of the differential signal.

In other words, in the modulator 100 in FIG. 5, roughly speaking, in the case where the FETs 121 and 124 to which the positive signal +BB is input are ON and the FETs 122 and 123 to which the negative signal −BB is input are OFF, a signal corresponding to the negative signal −LO of the carrier, the signal flowing in the FET 112, appears as the positive signal out1 of the modulation signal, and a signal corresponding to the positive signal +LO of the carrier, the signal flowing in the FET 111, appears as the negative signal out2 of the modulation signal, for example.

On the other hand, in the case where the FETs 121 and 124 are OFF and the FETs 122 and 123 are ON, a signal corresponding to the positive signal +LO of the carrier, the signal flowing in the FET 111, appears as the positive signal out1 of the modulation signal, and a signal corresponding to the negative signal −LO of the carrier, the signal flowing in the FET 112, appears as the negative signal out2 of the modulation signal.

Accordingly, signals obtained by BPSK-modulating the carrier appear according to the BB signal, as the positive signal out1 and the negative signal out2 of the modulation signal.

As described above, in the case where the BB signal itself is input to the modulator 100, the BPSK modulation is performed in the modulator 100, and the carrier is input to the gain stage 101 and the BB signal is input to the cascode stage 102, whereby change of the oscillation frequency of the oscillator 10 connected to the gain stage 101 due to the influence of the input impedance of the amplifier 40 and the influence of the BB signal can be suppressed, as described in FIG. 4.

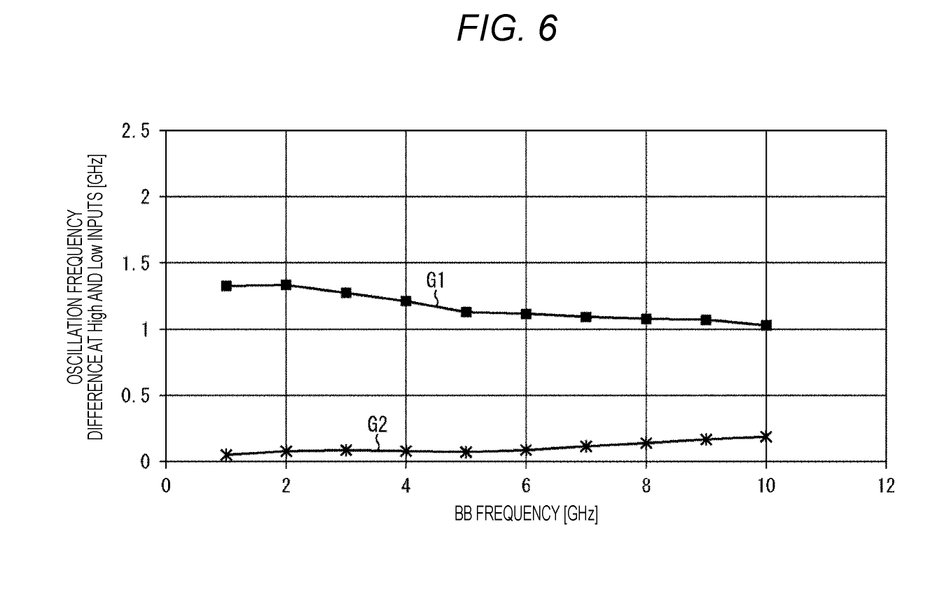

FIG. 6 is a diagram illustrating a simulation result of a simulation of measuring an error (change amount) of the oscillation frequency of the oscillator 10 configured without a PLL with respect to the frequency of the BB signal.

In FIG. 6, the horizontal axis represents the frequency of the BB signal, and the vertical axis represents the change amount of the oscillation frequency of the oscillator 10.

Graph G1 illustrates the change amount of the oscillation frequency of a case where the BB signal is input to the gain stage 101 and the carrier is input to the cascode stage 102. Graph G2 illustrates the change amount of the oscillation frequency of a case where the carrier is input to the gain stage 101 and the BB signal is input to the cascode stage 102.

According to FIG. 6, it can be confirmed that change of the oscillation frequency (the frequency of the carrier) is sufficiently suppressed in the case (graph G2) where the carrier is input to the gain stage 101 and the BB signal is input to the cascode stage 102, as compared with the case (graph G1) where the BB signal is input to the gain stage 101 and the carrier is input to the cascode stage 102.

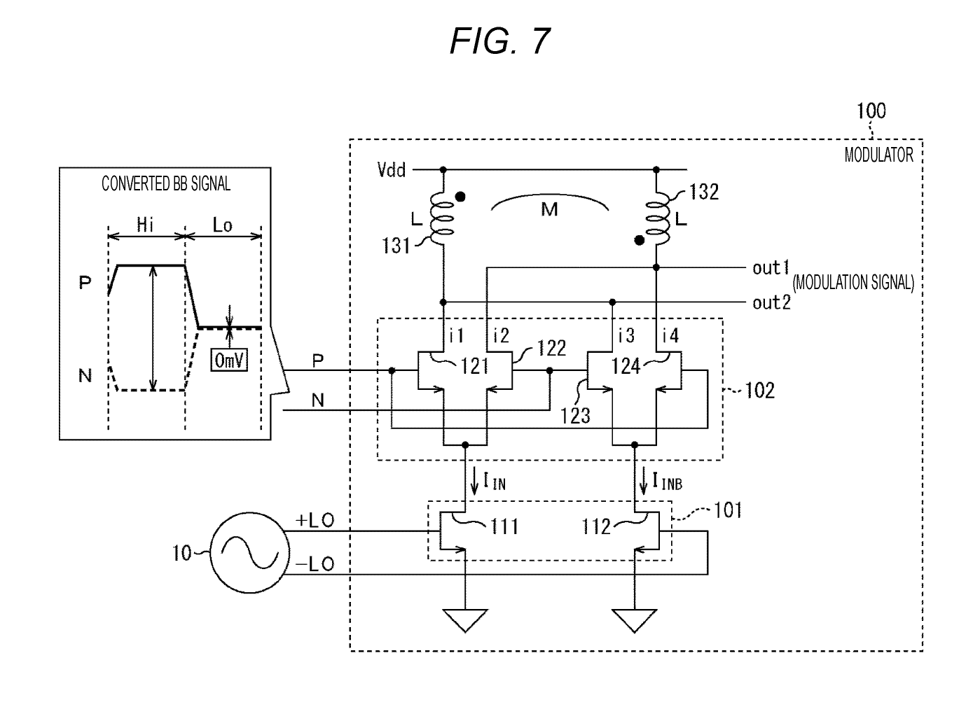

FIG. 7 is a diagram for describing an operation of the modulator 100 of a case where a converted BB signal, which is not the BB signal itself, is input to the cascode stage 102 in the first configuration of the cascode stage 102 in FIG. 5.

Note that, in FIG. 7, coils 131 and 132 having a predetermined mutual inductance M are respectively adopted as the loads 125 and 126 in FIG. 5.

In FIG. 7, the converted BB signal, which is not the BB signal itself, is input from the conversion unit 90 to the cascode stage 102.

In other words, in FIG. 7, as the first signal P and the second signal N constituting the converted BB signal, signals obtained by offsetting the positive signal +BB and the negative signal −BB of the BB signal in, for example, the L level section that is one of the H level section (Hi) and the L level section (Lo) of the positive signal +BB such that the levels coincide with each other are respectively adopted.

Here, currents flowing in the FETs 121, 122, 123, and 124 are denoted by i1, i2, i3, and i4, respectively, and currents flowing in the FETs 111 and 112 are denoted by I_{IN} and I_{INB}, respectively.

The currents I_{IN} and I_{INB} are signals corresponding to the positive signal +LO and the negative signal −LO of the carrier, respectively.

In the H level section, the currents I_{IN} and I_{INB} flow as the currents i1 and i4 respectively in the FETs 121 and 124 to which the first signal P at a higher level than the second signal N of the converted BB signal is input.

As a result, a signal corresponding to the current i1, in other words, the current I_{IN} corresponding to the positive signal +LO of the carrier appears at the output terminal out2 connected to the drain of the FET 121 in which the current i1 flows.

Furthermore, a signal corresponding to the current i4, in other words, the current I_{INB} corresponding to the negative signal −LO of the carrier appears at the output terminal out1 connected to the drain of the FET 124 in which the current i4 flows.

Meanwhile, since the levels of the first signal P and the second signal N of the converted BB signal are the same in the L level section, the currents i1 and i2 are equal to a current I_{IN}/2, and the currents i3 and i4 are equal to a current I_{INB}/2.

Since the currents I_{IN} and I_{INB} are reversed-phase currents with equal magnitude, the currents i1 and i3 become reversed-phase currents with equal magnitude and the currents i2 and i4 also become reversed-phase currents with equal magnitude.

As a result, a signal corresponding to a current 0 appears in an alternating current (AC) manner at the output terminal out2 connected to the drain of the FET 121 in which the current i1 flows and the drain of the FET 123 in which the reversed-phase current i3 to the current i1 flows.

Furthermore, a signal corresponding to a current 0 appears in an AC manner at the output terminal out1 connected to the drain of the FET 122 in which the current i2 flows and the drain of the FET 124 in which the reversed-phase current i4 to the current i2 flows.

Accordingly, a differential signal obtained by ASK-modulating the carrier at a modulation factor (degree) of 100% appear according to the BB signal, as the positive signal out1 and the negative signal out2 of the modulation signal.

As described above, as the first signal P and the second signal N constituting the converted BB signal, the signals obtained by offsetting the positive signal +BB and the negative signal −BB of the BB signal in the L level section such that the levels coincide with each other are respectively adopted, whereby the ASK modulation can be performed.

Note that, in FIG. 7, the carrier is input to the gain stage 101 and the converted BB signal is input to the cascode stage 102. However, the ASK modulation can be performed by inputting the converted BB signal to the gain stage 101 and inputting the carrier to the cascode stage 102.

Note that, as illustrated in FIG. 7, in the case where the carrier is input to the gain stage 101 and the converted BB signal is input to the cascode stage 102, change of the oscillation frequency of the oscillator 10 connected to the gain stage 101 can be suppressed, as described in FIG. 4.

<Configuration Example of Conversion Unit 90>

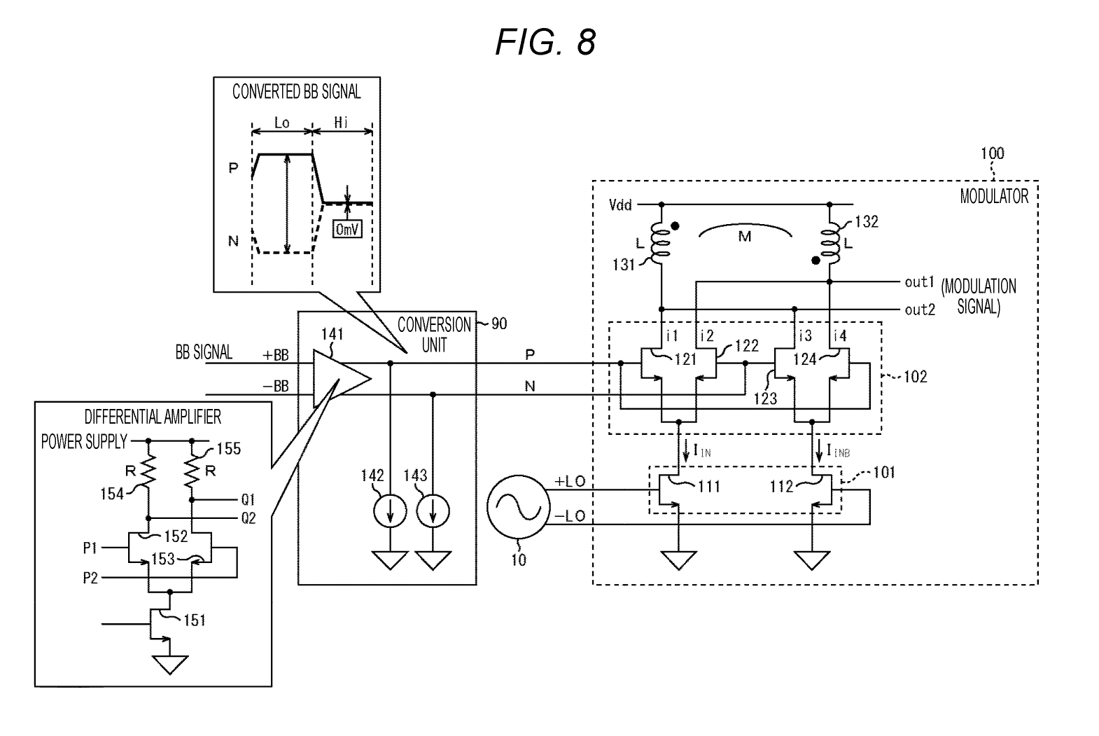

FIG. 8 is a diagram illustrating a first configuration example of the conversion unit 90 in FIG. 4.

In other words, FIG. 8 illustrates a configuration example of the conversion unit 90 of the case where the signals obtained by (inverting and amplifying and) offsetting the positive signal +BB and the negative signal −BB of the BB signal in the H level section of the negative signal −BB such that the levels coincide with each other are respectively adopted as the first signal P and the second signal N constituting the converted BB signal, as described in FIG. 7.

In FIG. 8, the conversion unit 90 includes a differential amplifier 141, and current supplies 142 and 143.

The differential amplifier 141 includes FETs 151, 152, and 153, and resistors 154 and 155.

The FET 151 is an N channel MOSFET and functions as a current supply. A predetermined bias voltage is applied to a gate of the FET 151. A source of the FET 151 is grounded, and a drain of the FET 151 is connected to sources of the FETs 152 and 153.

The FETs 152 and 153 are N channel MOSFETs, and sources are connected to each other to constitute a differential pair. A drain of the FET 152 is connected to the other end of the resistor 154 having one end connected to a power supply, and a drain of the FET 153 is connected to the other end of the resistor 155 having one end connected to the power supply.

A gate of the FET 152 is connected to an input terminal P1 of the differential amplifier 141, and a gate of the FET 153 is connected to an input terminal P2 of the differential amplifier 141.

A connection point between the FET 153 and the resistor 155 is connected to an output terminal Q1 of the differential amplifier 141, which outputs a positive signal of the differential signal, and a connection point between the FET 152 and the resistor 154 is connected to an output terminal Q2 of the differential amplifier 141, which outputs a negative signal of the differential signal.

The positive signal +BB and the negative signal −BB of the BB signal are respectively input to the input terminals P1 and P2 of the differential amplifier 141.

In the differential amplifier 141, the positive signal +BB and the negative signal −BB of the BB signal are inverted and amplified with a predetermined gain, and the negative signal −BB and the positive signal +BB after the inverted amplification are respectively output from the output terminals Q1 and Q2.

The current supplies 142 and 143 are respectively connected to the output terminals Q1 and Q2.

When the current supply 142 causes a current to flow in the output terminal Q1, the inverted negative signal −BB output from the output terminal Q1 is offset, whereby the first signal P of the converted BB signal is generated.

Furthermore, when the current supply 143 causes a current to flow in the output terminal Q2, the inverted positive signal +BB output from the output terminal Q2 is offset, whereby the second signal N of the converted BB signal is generated.

As described above, in the conversion unit 90, the first signal P and the second signal N constituting the converted BB signal are generated by inverting, amplifying, and offsetting the positive signal +BB and the negative signal −BB of the BB signal in the H level section (Hi) of the negative signal −BB such that the levels coincide with each other. In other words, in the conversion unit 90, the negative signal −BB of the BB signal is inverted, amplified, and offset, and the positive signal +BB of the BB signal is inverted, amplified, and offset, whereby the first signal P corresponding to the negative signal −BB is generated, and the second signal N at the same level as the first signal P in the H level section of the negative signal −BB is generated.

Then, by inputting the converted BB signal to the modulation circuit 100, the ASK modulation can be performed as described with reference to FIG. 7.

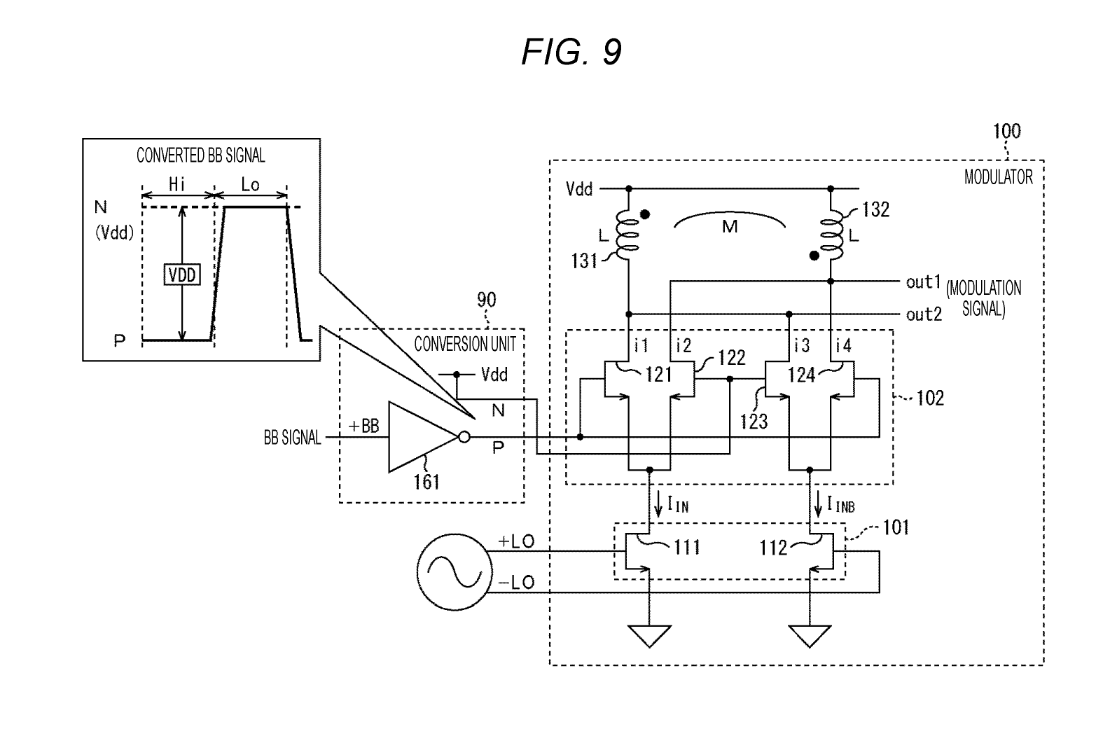

FIG. 9 is a diagram illustrating a second configuration example of the conversion unit 90 in FIG. 4.

In other words, FIG. 9 illustrates a configuration example of the conversion unit 90 of a case where a signal corresponding to one of the positive signal +BB and the negative signal −BB is adopted as the first signal P of the converted BB signal, and a fixed-level signal fixed to the level of the first signal P in one of the H level section and the L level section of the one of the positive signal +BB and the negative signal −BB is adopted as the second signal N of the converted BB signal, as described in FIG. 4.

In FIG. 9, the conversion unit 90 includes an inverter 161 and a power supply Vdd.

The positive signal +BB of the BB signal is input to the inverter 161. The inverter 161 inverts the positive signal +BB and outputs the inverted signal as the first signal P of the converted BB signal.

The first signal P of the converted BB signal output by the inverter 161 is at the L level in the H level section (the section where the positive signal +BB of the BB signal is at the H level) and is at the H level in the L level section.

Note that the H level output by the inverter 161 is equal to (the voltage of) the power supply Vdd.

In the conversion unit 90 in FIG. 9, (the voltage of) the power supply Vdd is output as the second signal N of the converted BB signal.

Accordingly, in the conversion unit 90 in FIG. 9, the signal corresponding to the negative signal −BB, for example, of the positive signal +BB and the negative signal −BB of the BB signal, is output as the first signal P of the converted BB signal, and the fixed-level signal fixed to the level of the first signal P (here, to the power supply voltage Vdd) in the L level section, for example, of the H level section and the L level section, is output as the second signal N of the converted BB signal.

As described above, the ASK modulation can be performed in the modulator 100 even in the case where the signal corresponding to the negative signal −BB is adopted as the first signal P of the converted BB signal, and the fixed-level signal fixed to the level of the first signal P in the L level section is adopted as the second signal N of the converted BB signal.

Note that, in the case where the fixed-level signal is adopted as the second signal N, the power supply voltage Vdd or the GND can be adopted as the fixed level, for example. In this case, resistance to process, voltage and temperature (PVT) variation can be improved.

<Second Configuration Example of Cascode Stage 102>

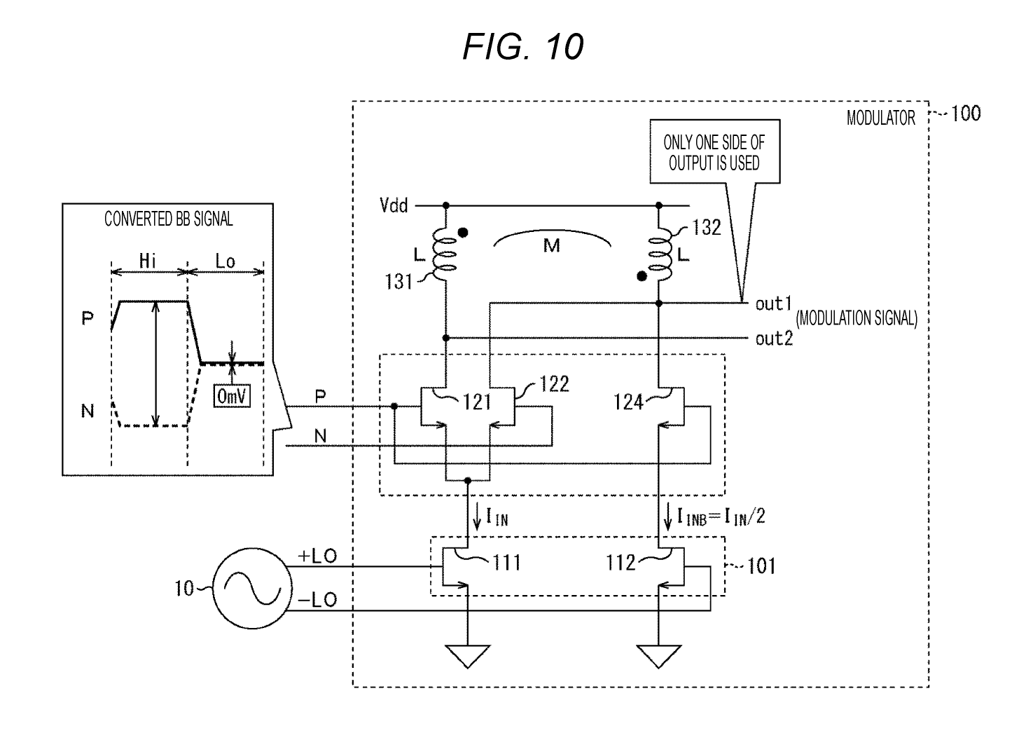

FIG. 10 is a diagram illustrating a second configuration example of the cascode stage 102 in FIG. 4.

Note that, in the drawing, a portion corresponding to the case of FIG. 5 is denoted by the same reference numeral, and description of the portion is herein appropriately omitted.

Furthermore, in FIG. 10, coils 131 and 132 having a predetermined mutual inductance M are respectively adopted as the loads 125 and 126 in FIG. 5, similarly to FIG. 7.

The cascode stage 102 in FIG. 10 includes the one differential pair configured by FETs 121 and 122 and the one FET 124.

Therefore, the cascode stage 102 in FIG. 10 is common to the case in FIG. 5 in including the differential pair configured by the FETs 121 and 122, and including the FET 124.

However, the cascode stage 102 in FIG. 10 is different from the case in FIG. 5 in not provided with the FET 123 and therefore in not including the differential pair configured by the FETs 123 and 124.

In FIG. 10, the signals obtained by offsetting the positive signal +BB and the negative signal −BB of the BB signal in the L level section such that the levels coincide with each other are input to the cascode stage 102, as the first signal P and the second signal N constituting the converted BB signal, whereby the ASK modulation can be performed, for example.

In other words, in the cascode stage 102, the first signal P is input to the FETs 121 and 124, and the second signal N is input to the FET 122.

Accordingly, in the modulator 100, the ASK modulation is performed, similarly to the case in FIG. 7, and a modulation signal obtained through the ASK modulation, similar to FIG. 7, appears at the output terminal out1 connected to the drains of the FETs 122 and 124.

Note that in FIG. 7, the drain of the FET 123 is connected to the output terminal out2, whereas in FIG. 10, the cascode stage 102 is configured without the FET 123 and thus the FET 123 is not connected to the output terminal out2.

Accordingly, the signal appearing at the output terminal out2 in FIG. 10 is different from the signal appearing at the output terminal out2 in FIG. 7. Therefore, in FIG. 10, the signal output from the output terminal out1 connected to the drains of the FETs 122 and 124 is used as the modulation signal of the single-ended signal.

<Third Configuration Example of Cascode Stage 102>

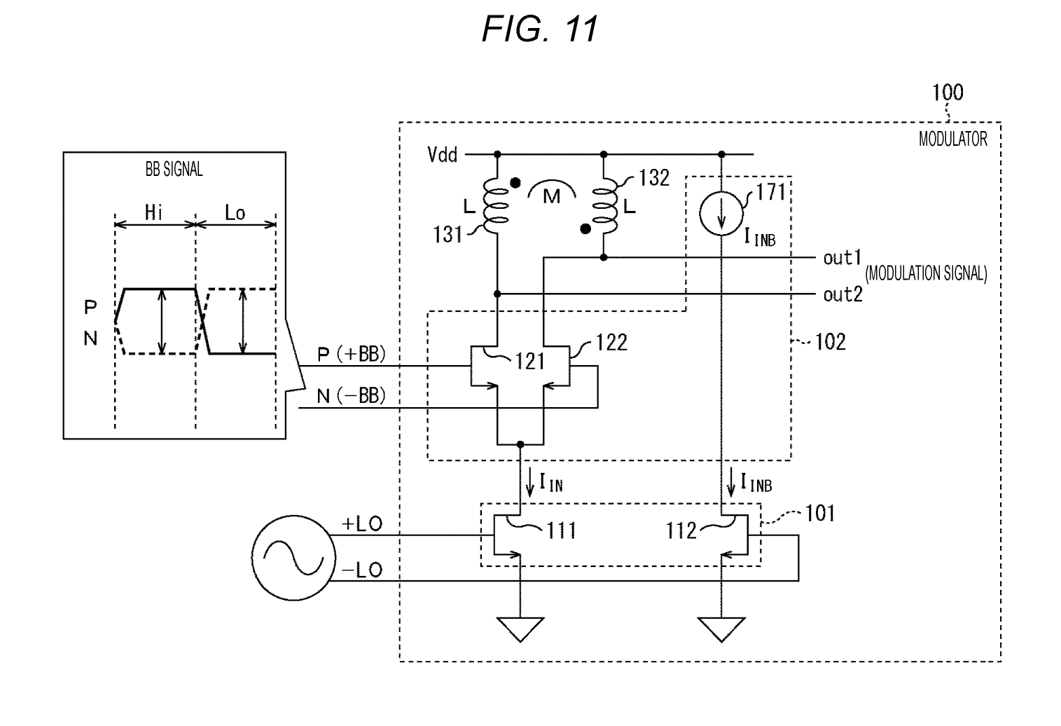

FIG. 11 is a diagram illustrating a third configuration example of the cascode stage 102 in FIG. 4.

Note that, in the drawing, a portion corresponding to the case of FIG. 5 is denoted by the same reference numeral, and description of the portion is herein appropriately omitted.

Furthermore, in FIG. 11, coils (inductances) 131 and 132 having a predetermined mutual inductance M are respectively adopted as the loads 125 and 126 in FIG. 5, similarly to FIG. 7.

The cascode stage 102 in FIG. 11 includes the one differential pair configured by FETs 121 and 122 and a current supply 171.

Therefore, the cascode stage 102 in FIG. 11 is common to the case in FIG. 5 in including the differential pair configured by the FETs 121 and 122.

However, the cascode stage 102 in FIG. 11 is different from the case in FIG. 5 in not provided with the FETs 123 and 124, and in including the current supply 171.

In FIG. 11, the ASK modulation can be performed by inputting, for example, the positive signal +BB and the negative signal −BB themselves of the BB signal to the cascode stage 102, as the first signal P and the second signal N constituting the converted BB signal, for example.

In other words, in FIG. 11, the positive signal +BB of the BB signal is input to the FET 121, and the negative signal −BB of the BB signal is input to the FET 122.

In the FET 121, the current corresponding to the positive signal +LO of the carrier to be input to the FET 111 flows according to the positive signal +BB. As a result, the signal obtained by ASK-modulating (the signal corresponding to) the positive signal +LO of the carrier appears according to the positive signal +BB at the output terminal out2 connected to the drain of the FET 121.

Meanwhile, in the FET 122, the current corresponding to the positive signal +LO of the carrier to be input to the FET 111 flows according to the negative signal −BB. As a result, the signal obtained by ASK-modulating the positive signal +LO of the carrier appears according to the negative signal −BB at the output terminal out1 connected to the drain of the FET 121.

Accordingly, in FIG. 11, the ASK modulation is performed in the modulator 100, and the modulation signals obtained through the ASK modulation appear as a differential signal at the output terminals out1 and out2.

The modulation system to which the present technology is applied has been described. The modulation system of the present technology can be applied in the millimeter wave communication, and other arbitrary band communication.

Here, in the present specification, the term “system” means a group of a plurality of configuration elements (devices, modules (parts), and the like), and whether or not all the configuration elements are in the same casing is irrelevant. Accordingly, a plurality of devices that is housed in separate casings and connected via a network, and one device that houses a plurality of modules in one casing are both systems.

Note that an embodiment of the present technology is not limited to the above-described embodiment, and various changes can be made without departing from the gist of the present technology.

Furthermore, the effects described in the present specification are merely examples and are not limited, and other effects may be exhibited.

Note that the present technology can be configured as follows.

<1>

A modulator

configured to be input

a first signal corresponding to one of a positive signal and a negative signal constituting a baseband signal of a differential signal, and

a second signal at the same level as the first signal in one of an H level section in which the one of the positive signal and the negative signal is at an H level and an L level section in which the one of the positive signal and the negative signal is at an L level, and

configured to modulate a carrier with the first and second signals to generate a modulation signal that is the amplitude shift keying (ASK)-modulated carrier with the baseband signal.

<2>

The modulator according to <1>, in which the second signal is a fixed-level signal.

<3>

The modulator according to <1>, in which the first signal is a signal obtained by offsetting the one of the positive signal and the negative signal, and the second signal is a signal obtained by offsetting the other of the positive signal and the negative signal.

<4>

The modulator according to any one of <1> to <3>, configured by a cascode circuit including

a gain stage to which the carrier is input, and

a cascode stage to which the first and second signals are input.

<5>

The modulator according to <4>, in which

the gain stage includes two transistors to which a carrier of a differential signal is input.

<6>

The modulator according to <4> or <5>, in which the cascode stage includes two differential pairs to which the first and second signals are respectively input.

<7>

The modulator according to <4> or <5>, in which the cascode stage includes

a differential pair to which the first and second signals are input, and

a transistor to which one of the first and second signals is input.

<8>

The modulator according to <4> or <5>, in which

the cascode stage includes a differential pair to which the first and second signals are input.

<9>

The modulator according to any one of <4> to <8>, in which an inductance is included as a load of the cascode circuit.

<10>

A modulation method including:

modulating a carrier with

a first signal corresponding to one of a positive signal and a negative signal constituting a baseband signal of a differential signal, and

a second signal at the same level as the first signal in one of an H level section in which the one of the positive signal and the negative signal is at an H level and an L level section in which the one of the positive signal and the negative signal is at an L level,

to generate a modulation signal that is the amplitude shift keying (ASK)-modulated carrier with the baseband signal.

<11>

A modulator

configured by

a cascode circuit including

a gain stage to which a carrier of a differential signal is input, and

a cascode stage to which a baseband signal is input, and configured to modulate the carrier with the baseband signal.

<12>

The modulator according to <11>, in which

the gain stage includes two transistors to which a carrier of a differential signal is input.

<13>

The modulator according to <11> or <12>, in which

the cascode stage includes two differential pairs to which a baseband signal of a differential signal is input.

<14>

The modulator according to <11> or <12>, in which

the cascode stage includes

a differential pair to which a baseband signal of a differential signal is input, and

a transistor to which one of a positive signal and a negative signal constituting the baseband signal of the differential signal is input.

<15>

The modulator according to <11> or <12>, in which

the cascode stage includes a differential pair to which a baseband signal of a differential signal is input.

<16>

The modulator according to any one of <11> to <15>, in which

an inductance is included as a load of the cascode circuit.

<17>

A modulation method including:

inputting a differential signal of a carrier to a gain stage of a cascode circuit including the gain stage and a cascode stage, and inputting a baseband signal to the cascode stage; and

modulating the carrier with the baseband signal.

### REFERENCE SIGNS LIST

10 Oscillator
20 Modulator
21 Gain stage
22 Cascode stage
23 Resistor
31, 32 FET
40 Amplifier
50 Modulator
51 Gain stage
52 Cascode stage
53, 54 Resistor
61 to 63 FET
70 Modulator
71 Gain stage
72 Cascode stage
73, 74 Resistor
81 to 86 FET
90 Conversion unit
100 Modulator
101 Gain stage
102 Cascode stage
103 Load
111, 112 FET
121 to 124 FET
125, 126 Load
131, 132 Coil
141 Differential amplifier
142, 143 Current supply
151 to 153 FET
154, 155 Resistor
161 Inverter
171 Current supply

1. A modulator
configured to be input
a first signal corresponding to one of a positive signal and a negative signal constituting a baseband signal of a differential signal, and
a second signal at a same level as the first signal in one of an H level section in which the one of the positive signal and the negative signal is at an H level and an L level section in which the one of the positive signal and the negative signal is at an L level, and
configured to modulate a carrier with the first and second signals to generate a modulation signal that is the amplitude shift keying (ASK)-modulated carrier with the baseband signal.

2. The modulator according to claim 1, wherein
the second signal is a fixed-level signal.

3. The modulator according to claim 1, wherein
the first signal is a signal obtained by offsetting the one of the positive signal and the negative signal, and the second signal is a signal obtained by offsetting the other of the positive signal and the negative signal.

4. The modulator according to claim 1, configured by a cascode circuit including
a gain stage to which the carrier is input, and
a cascode stage to which the first and second signals are input.

5. The modulator according to claim 4, wherein
the gain stage includes two transistors to which a carrier of a differential signal is input.

6. The modulator according to claim 4, wherein
the cascode stage includes two differential pairs to which the first and second signals are respectively input.

7. The modulator according to claim 4, wherein
the cascode stage includes
a differential pair to which the first and second signals are input, and
a transistor to which one of the first and second signals is input.

8. The modulator according to claim 4, wherein
the cascode stage includes a differential pair to which the first and second signals are input.

9. The modulator according to claim 4, wherein
an inductance is included as a load of the cascode circuit.

10. A modulation method comprising:
modulating a carrier with
a first signal corresponding to one of a positive signal and a negative signal constituting a baseband signal of a differential signal, and
a second signal at a same level as the first signal in one of an H level section in which the one of the positive signal and the negative signal is at an H level and an L level section in which the one of the positive signal and the negative signal is at an L level,
to generate a modulation signal that is the amplitude shift keying (ASK)-modulated carrier with the baseband signal.

11. A modulator
configured by
a cascode circuit including
a gain stage to which a carrier of a differential signal is input, and
a cascode stage to which a baseband signal is input, and
configured to modulate the carrier with the baseband signal.

12. The modulator according to claim 11, wherein
the gain stage includes two transistors to which a carrier of a differential signal is input.

13. The modulator according to claim 11, wherein
the cascode stage includes two differential pairs to which a baseband signal of a differential signal is input.

14. The modulator according to claim 11, wherein
the cascode stage includes
a differential pair to which a baseband signal of a differential signal is input, and
a transistor to which one of a positive signal and a negative signal constituting the baseband signal of the differential signal is input.

15. The modulator according to claim 11, wherein
the cascode stage includes a differential pair to which a baseband signal of a differential signal is input.

16. The modulator according to claim 11, wherein
an inductance is included as a load of the cascode circuit.

17. A modulation method comprising:
inputting a differential signal of a carrier to a gain stage of a cascode circuit including the gain stage and a cascode stage, and inputting a baseband signal to the cascode stage; and
modulating the carrier with the baseband signal.
